(19) United States
(12) Patent Application Publication
(10) Pub. No.: US 2011/0291291 A1
(43) Pub. Date: Dec. 1, 2011

(54) Silicon Chip Having Penetrative Connection Holes

(75) Inventors: Tung-Sheng Lai, Taoyuan County (TW); Tse Min Chu, Taoyuan County (TW)

(73) Assignee: MAO BANG ELECTRONIC CO., LTD., Taoyuan County (TW)

(21) Appl. No.: 13/041,669

(22) Filed: Mar. 7, 2011

(30) Foreign Application Priority Data
May 27, 2010 (TW) 099210033

(51) Int. Cl. H01L 23/48

(52) U.S. Cl. 257/774; 257/E23.011

(57) ABSTRACT

Two circuit layout areas on two surfaces of a chip are connected. Holes in the chip are coordinated with a conductive paste to connect the two surfaces. Thus, fabrication is made easy and cost is reduced.

### TECHNICAL FIELD OF THE DISCLOSURE

The present disclosure relates to coordinating holes in a chip with a conductive paste for connecting two circuit layout areas on two surfaces of the chip with easy fabrication and low cost.

### DESCRIPTION OF THE RELATED ART

In a general semiconductor fabrication, holes are set in a related chip and each hole is set with a conductive layer to connect two surfaces of the chip. A common procedure includes drilling a plurality of holes in the chip and then forming a conductive layer on an inner surface of each hole through a process of chemical vapor deposition (CVD), physical vapor deposition (PVD), electrical plating, non-electrical plating, etc. Thus, the two surfaces of the chip are connected.

However, the above procedure, including drilling holes and forming conductive layer through a process like CVD, PVD, etc. is complex and is expensive. Hence, the prior art does not fulfill all users' requests on actual use.

### SUMMARY OF THE DISCLOSURE

The main purpose of the present disclosure is to coordinate holes in a chip with a conductive paste for connecting two circuit layout areas on two surfaces of the chip with easy fabrication and low cost

To achieve the above purpose, the present disclosure is a silicon (Si) chip having penetrative connection holes, comprising a chip and a conductive paste, where the chip has two circuit layout areas on two surfaces of the chip; the chip has a plurality of holes penetrating through the chip; the chip further has a pattern die deposed on a surface; the pattern die has a plurality of channels corresponding to the plurality of holes; and the conductive paste is filled into the plurality of holes through the plurality of channels to connect the two circuit layout areas on the two surfaces of the chip. Accordingly, a novel Si chip having penetrative connection holes is obtained.

### BRIEF DESCRIPTIONS OF THE DRAWINGS

The present disclosure will be better understood from the following detailed description of the preferred embodiment according to the present disclosure, taken in conjunction with the accompanying drawings, in which

FIG. 1 is the perspective view showing the preferred embodiment according to the present disclosure;

FIG. 2 is the sectional view showing the preferred embodiment;

FIG. 3 and FIG. 4 are the views showing the first state of use; and

FIG. 5 and FIG. 6 are the views showing the second state of use.

### DESCRIPTION OF THE PREFERRED EMBODIMENT

The following description of the preferred embodiment is provided to understand the features and the structures of the present disclosure.

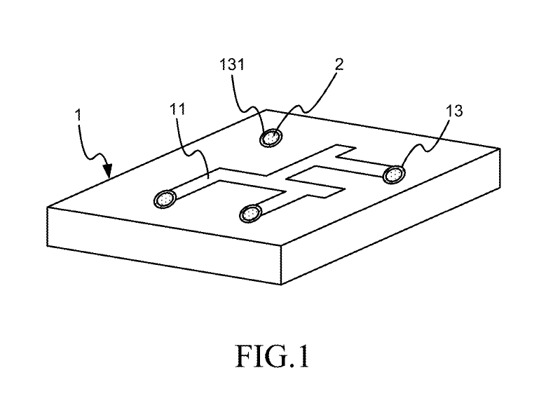

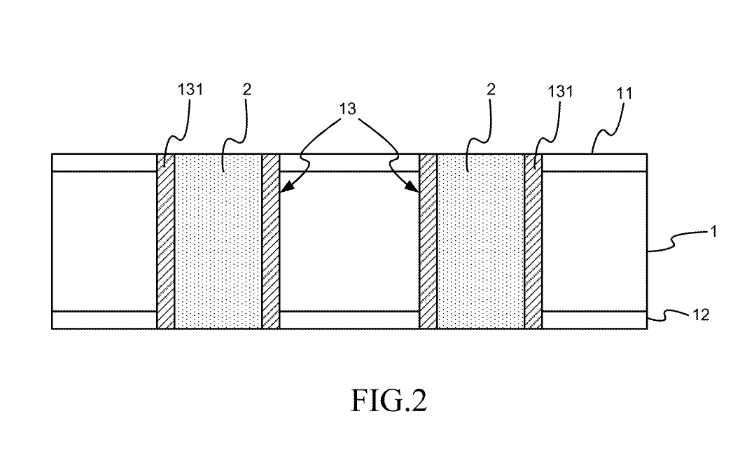

Please refer to FIG. 1 and FIG. 2, which are a perspective and a sectional views showing a preferred embodiment according to the present disclosure. As shown in the figures, the present disclosure is a silicon (Si) chip having penetrative connection holes, comprising a chip 1 and a conductive paste 2.

The chip 1 has two circuit layout areas 11,12 on two surfaces separately, where the chip 1 has a plurality of holes 13 penetrating the circuit layout areas 11,12; each of the holes 13 has a diameter below 100 micrometers (μm); the chip 1 is made of Si or sapphire; and an inner surface of each of the holes 13 is covered with a conductive layer 131 (or, the conductive layer 131 can be omitted according to requirement.)

The conductive paste 2 is filled into the plurality of holes 13 to connect the two circuit layout areas 11,12 on the two surfaces of the chip 1. Thus, a novel Si chip having penetrative connection holes is obtained.

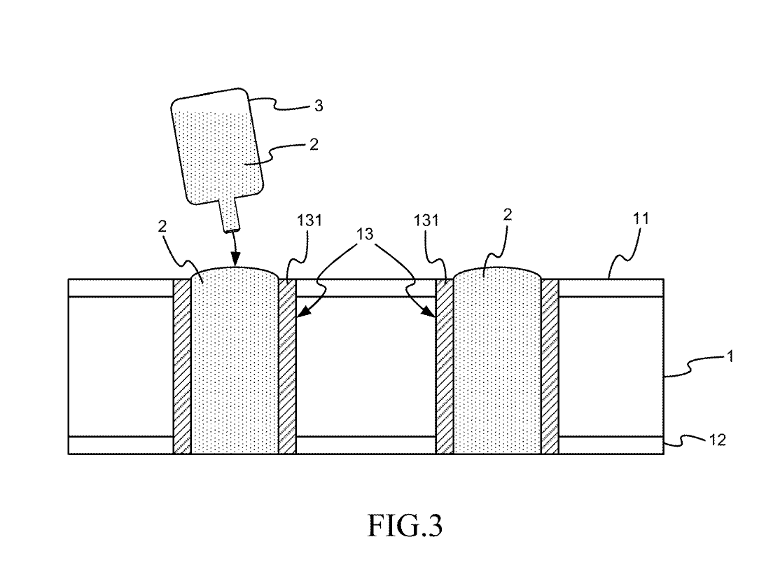

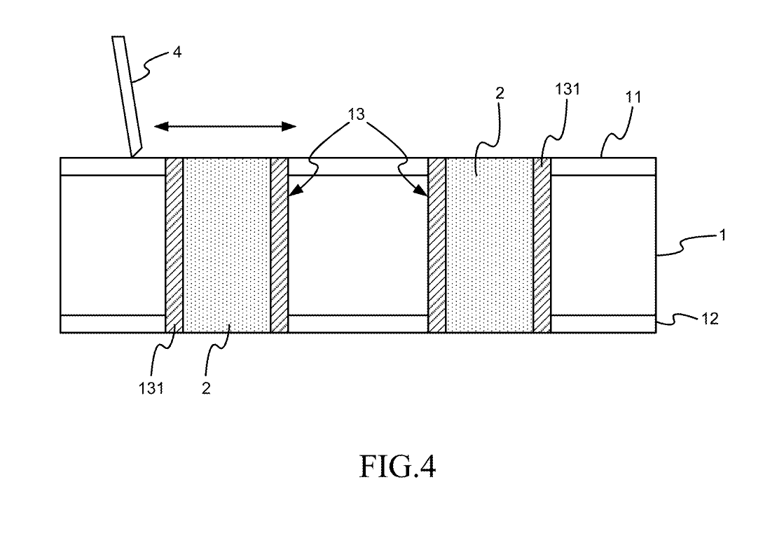

Please further refer to FIG. 3 and FIG. 4, which are views showing a first state of use. As shown in the figures, on using the present disclosure, the conductive paste 2 is contained in a container 3 and the container 3 is squeezed to fill the conductive paste 2 into each of the holes 13 for connecting the two circuit layout areas 11,12 on the two surfaces of the chip 1. Because the conductive paste 2 will have some extra paste overflowed from the holes after filling, a blade 4 can be used to scrape the conductive paste 2 off back and forth on a surface (or two surfaces) of the chip 1

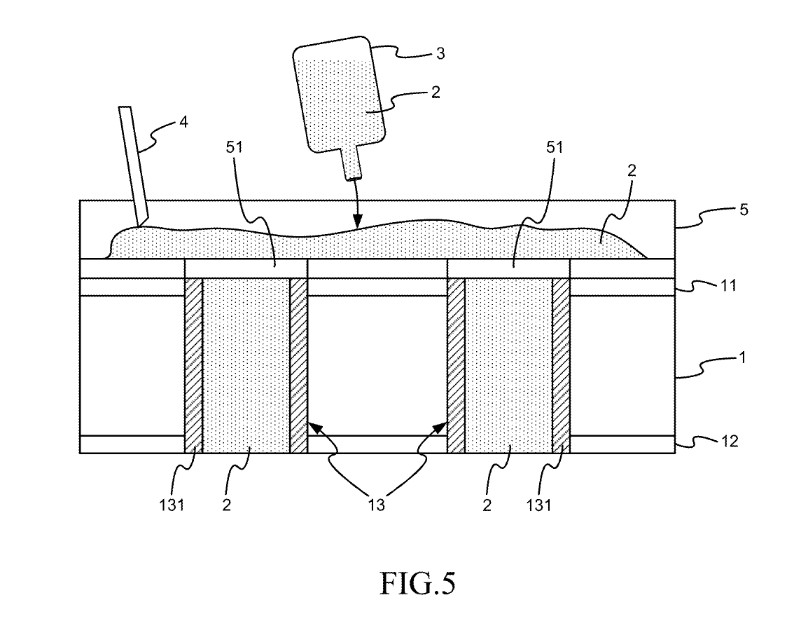

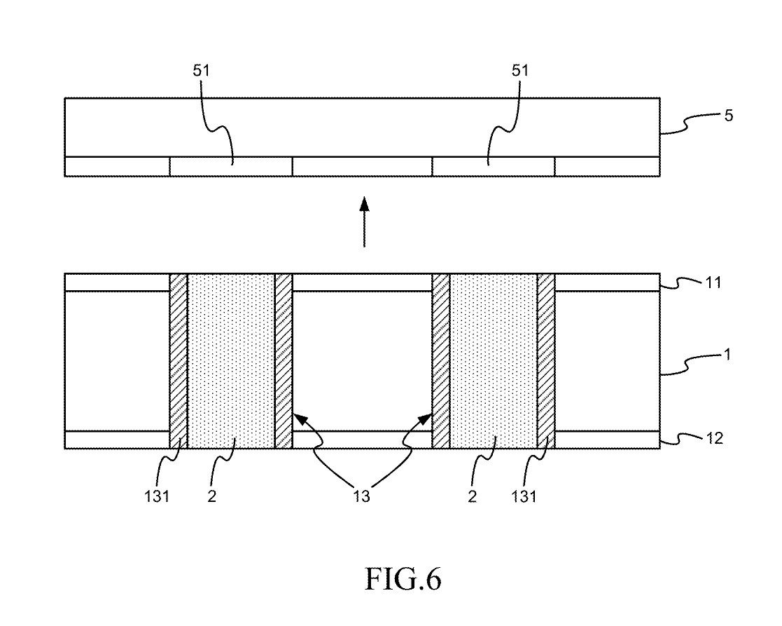

Please further refer to FIG. 5 and FIG. 6, which are views showing a second state of use. As shown in the figures, on using the present disclosure, a pattern die 5 can be further correspondingly set on a surface of the chip 1, where a plurality of channels 51 is formed in the pattern die 5 corresponding to the plurality of holes 13 in the chip 1. The conductive paste 2 in the container 3 is directly squeezed on the pattern die 5 for filling the conductive paste 2 into the holes 13. Then, the conductive paste 2 is scraped off back and forth on the pattern die 5 with a blade 4. Therein, the conductive paste 2 is filled into the holes 13 through the channels 51 with coordination of the blade 4. Then, the pattern die 5 is removed from the surface of the chip 1. Thus, the two circuit layout areas 11,12 on the two surfaces of the chip 1 are connected.

To sum up, the present disclosure is a silicon chip having penetrative connection holes, where holes in a chip is coordinated with a conductive paste to connect two circuit layout areas on two surfaces of the chip with easy fabrication and low cost.

The preferred embodiment herein disclosed is not intended to unnecessarily limit the scope of the disclosure. Therefore, simple modifications or variations belonging to the equivalent of the scope of the claims and the instructions disclosed herein for a patent are all within the scope of the present disclosure.

What is claimed is:

1. A silicon chip having penetrative connection holes, comprising:
a chip, said chip having two circuit layout areas on two surfaces of said chip separately, said chip having a plurality of holes penetrating through said chip, each of said holes having a diameter below 100 micrometers (μm); and
a conductive paste, said conductive paste being filled into said plurality of holes to connect said two circuit layout areas on said two surfaces of said chip.

2. The silicon chip according to claim 1,
wherein said chip is made of silicon (Si).

3. The silicon chip according to claim 1,
wherein said chip is made of sapphire.

4. The silicon chip according to claim 1,
wherein an inner surface of each of said holes is covered with a conductive layer.

5. The silicon chip according to claim 1,
wherein said conductive paste is contained in a container to be filled into said plurality of holes and then is scraped off on said two surfaces of said chip with a blade.

6. The silicon chip according to claim 1,
wherein said chip further has a pattern die deposed on a surface of said chip;
wherein said pattern die has a plurality of channels corresponding to said plurality of holes; and
wherein said conductive paste is filled into said plurality of holes through said plurality of channels.
